(19) United States
(12) Patent Application Publication
(10) Pub. No.: US 2016/0202401 A1
(43) Pub. Date: Jul. 14, 2016

(54) A NANOSTRUCTURED SURFACE FOR GREY SCALE COLOURING

(71) Applicant: DANMARKS TEKNISKE UNIVERSITET, Lyngby (DK)

(72) Inventors: Alexander Bruun Christiansen, Copenhagen Ø (DK); Anders Kristensen, Frederiksberg C (DK); Niels Asger Mortensen, Kgs. Lyngby (DK)

(21) Appl. No.: 14/914,860

(22) PCT Filed: Sep. 2, 2014
(86) PCT No.: PCT/DK2014/050266

§ 371 Date: Feb. 26, 2016

(30) Foreign Application Priority Data
Sep. 2, 2013 (EP) 13182669.5
Jun. 18, 2014 (DK) PA 2014 70365

(51) Int. Cl. G02B 5/22; B29C 37/00; G02B 5/02; C23C 14/02; F21V 9/08; B29C 59/02; C23C 14/34

(52) U.S. Cl. CPC G02B 5/22; B29C 59/02; B29C 37/0025; C23C 14/34; C23C 14/028; F21V 9/08; G02B 5/0221; B29L 2031/3475

(57) ABSTRACT

The invention relates to a nanostructured product with a structurally coloured surface. The structurally coloured surface is obtained by providing a nanostructured surface on a substrate which may be a plastic material, and by providing a covering metal layer on the nanostructured surface. The metal layer generates broad band absorbance of light in a visible spectral range so that the structurally coloured surface appears dark, e.g. appears to have a grey or black colour.

### FIELD OF THE INVENTION

The invention relates to nanostructured surfaces, specifically to structural colouring by use of such surfaces.

### BACKGROUND OF THE INVENTION

It is known to decorate plastic objects by painting with a coloured painting material. The painting will adhere to the object after it has dried. Other methods for providing plastic objects with a coloured decoration exist. Normally such methods complicate the manufacturing process of the plastic objects since the process in addition to forming the plastic object includes various steps for applying the decoration.

Furthermore, painted products may complicate recycling of such products since the paint has to be removed before recycling the main object since the paint may otherwise add undesired colouring to the recycling material, e.g. a white colour of a main material will be polluted by black paint.

Accordingly, there is a need for other colouring processes for decorating objects which may not suffer from the above problems or which offer other advantages.

WO2013039454 discloses an optical arrangement which includes a substrate, and a plurality of spaced apart elongate nanostructures extending from a surface of the substrate, wherein each elongate nanostructure includes a metal layer on the end distal from the surface of the substrate. The present invention also relates to a method of forming the optical arrangement.

### SUMMARY OF THE INVENTION

It would be advantageous to achieve improvements within methods for decorating metal or polymer objects. In particular, it may be seen as an object of the present invention to provide a method that solves the above mentioned problems relating to colouring and/or recycling, or other problems, of the prior art.

To better address one or more of these concerns, in a first aspect of the invention a nanostructured product with a structurally coloured surface is presented that comprises
a substrate comprising a nanostructured surface, comprising raised or depressed nanostructures, and
a metal layer at least partially covering the nanostructured surface and at least partially conforming to the nanostructured surface so that the metal layer generates broad band absorbance of light in a visible spectral range.

For example a plastic object such as a toy may comprise the nanostructured product according to the first aspect. The plastic object and the substrate may be made of different materials or of the same material so that only a metal layer need to be added to the object in order to decorate the object with a colouring, here a dark, e.g. grey or black colour. Since only a thin metal layer, but no additional colours, is introduced in the object or substrate to create the desired colouring the object may be recycled many times, e.g. a hundred times or more, without destroying the original colour of the object or substrate.

The metal layer generates absorption in a spectral range of the visible spectral range, i.e. in a range, which covers at least 100 nanometre of the visible range from 380 to 700 nanometre. In practice, the metal layer should generate absorption over the entire or substantially the entire visible range in order to generate broad band absorption. Accordingly, broad band absorption may be defined as absorption in a spectral range of at least 100 nm within the visible range from 380 to 700 nanometre. The absorption may be greater than 20 percent in average over the visible spectral range or over a sub-range of at least 100 nm within the visible range. The book: “Optical Materials: An Introduction to Selection and Application, Optical Engineering volume 6, 1985, by Solomon Musikant, published by Marcel Dekker, Inc.” provides several examples of spectral ranges of broad band antireflection filters. An example of a broad band AR coating which is effective in the spectral range from 400 to 750 nm is given on page 162.

The nanostructured surface normally covers an area larger than e.g. at least 4 square millimetres. Thus, over a relatively large area, e.g. at least 4 square millimetres the nanostructured surface has the same or substantially the same optical properties with respect to absorption.

The nanostructured colouring may be provided to opaque or transparent substrates. In an embodiment the substrate is a plastic or polymer. In an alternative embodiment the substrate is an oxide layer on a metal.

In an embodiment the average broad band absorption of light in a visible spectral range is greater than 20 percent in average over the visible spectral range. Absorption of 20 percent of the power of incident light on the substrate may be sufficient to generate a dark surface.

In an embodiment the metal layer on the nanostructured surface has a reflectance of light in a visible spectral range which is less than 20 percent in average over the visible spectral range. Reflection of less than 20 percent of the power of incident light on the substrate improves the darkness of the nanostructured surface.

Preferably, the metal layer conforms to the nanostructured surface so that the metal layer comprises a nanostructured surface comprising raised or depressed structures similar to the nanostructured surface of the substrate.

In an embodiment the raised or depressed nanostructures of the substrate projects from a base plane, so that the raised or depressed nanostructures of the conforming metal layer also projects from a base plane of the metal layer, wherein the coverage of the raised or depressed structures of the metal layer relative to the base plane of the metal layer is greater than 30 percent.

In an embodiment the substrate further comprises a scattering surface. The scattering surface may comprise structures having dimensions which are large enough to scatter incoming visible light.

The scattering surface may be located adjacent to nanostructured surface so as to provide a contrast to the dark nanostructured surface.

The substrate may comprise a plurality of the scattering surfaces and a plurality of the nanostructured surfaces arranged in a pattern with alternating scattering surfaces and nanostructured surfaces. Such a pattern may be used for creating a particular level of grey.

In an embodiment the substrate further comprises a non-structured surface covered by the metal layer. The non-structured surface may be used for generating a reflective surface, e.g. adjacent to the nanostructured dark surface.

In an embodiment the substrate is a foil, wherein the metal layer is located on a back face of the foil, and wherein the back face is configured to be connected to an object.

In an embodiment the metal layer is covered with a protective transparent layer. Such a protective layer may advantageously be used for protecting the nanostructures in the substrate and the metal layer.

A second aspect of the invention relates to a display comprising
the nanostructured product according to the first aspect, and
a light source arranged to emit light towards the nanostructured product.

The light source may be any source capable of emitting light directly or indirectly towards the nanostructured product. For example, the light source may emit a beam of light directly towards the nanostructured product. Alternatively, the light source may be configured to emit light indirectly towards the nanostructured product, e.g. by emitting light towards a reflecting or scattering layer so that the reflected or scattered light is directed towards the nanostructured product.

The light source may be configured to direct a beam of light towards the nanostructured product, e.g. a beam with uniform beam intensity, or to direct a pattern of different light intensities and/or colours, e.g. a pattern generated by an LCD screen, towards the nanostructured product.

A third aspect of the invention relates to a process for manufacturing the nanostructured product according to the first aspect, comprising
forming a plastic object by moulding or embossing by use of a mould or embossing tool, wherein a surface of the mould or embossing tool is provided with a nanostructured surface, so that the forming creates a nanostructured surface of the plastic object,
covering the nanostructured surface of the plastic object with a metal layer so that the metal layer at least partially covers the nanostructured surface and at least partially conforms to the nanostructured surface so that the metal layer generates broad band absorption of light in a visible spectral range.

In summary the invention relates to a nanostructured product with a structurally coloured surface. The structurally coloured surface is obtained by providing a nanostructured surface on a substrate which may be a plastic material, and by providing a covering metal layer on the nanostructured surface. The metal layer generates broad band absorbance of light in a visible spectral range so that the structurally coloured surface appears dark, e.g. appears to have a grey or black colour.

In general the various aspects of the invention may be combined and coupled in any way possible within the scope of the invention. These and other aspects, features and/or advantages of the invention will be apparent from and elucidated with reference to the embodiments described hereinafter.

### BRIEF DESCRIPTION OF THE DRAWINGS

Embodiments of the invention will be described, by way of example only, with reference to the drawings, in which

FIG. 1 illustrates the nanostructures 103 in nanostructured product 100,

FIG. 2 shows measured nanostructured surfaces 102 and metal layers 105,

FIG. 3A illustrates cross-sectional views of different principal shapes of raised nanostructures 103,

FIG. 3B illustrates top views of the cross-sectional views from FIG. 3A for point-like structures 321 and elongate structures 322,

FIGS. 4A-C show experimentally obtained absorbance values 401 and reflectance values 402,

FIG. 5 shows an alternative embodiment of the nanostructured surface 102, wherein the nanostructures are arranged in a binary pattern,

FIGS. 6-10 show measurement results, and

FIGS. 11A-B illustrate application of the nanostructured product 100 in a display 10.

### DESCRIPTION OF AN EMBODIMENT

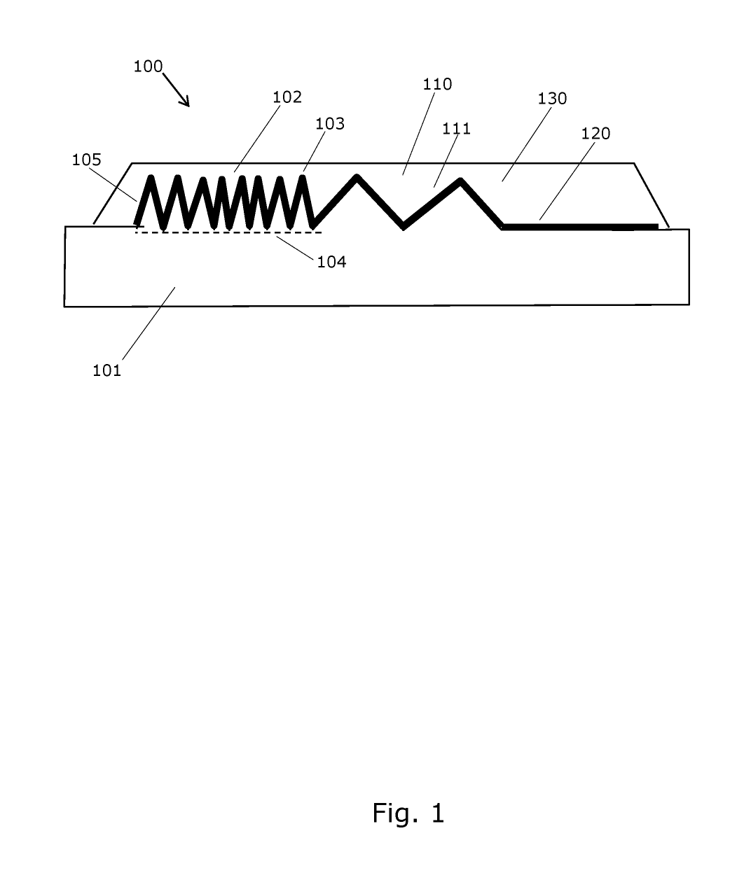

FIG. 1 principally illustrates a nanostructured product 100 with a structurally coloured surface. The product 100 includes a substrate 101 which includes a nanostructured surface 102 having raised or depressed nanostructures 103. The nanostructures 103 may be seen as elongate structures, e.g. pins or holes, protruding out from or into the substrate. The nanostructured surface defines a base plane 104, which may be a generally flat surface or a curved surface, which the nanostructures 103 projects into or out from.

Structural colouring refers to colouring caused by optical effects due to the nanostructures instead of colouring caused by coloured pigments.

The nanostructured surface 102 is provided with a metal layer 105 which at least partially covers the nanostructured surface and at least partially conforms to the nanostructured surface. A metal layer normally absorbs a small amount of the light energy and reflects or scatters a relatively large amount of the light energy. However, when the metal layer 105 is nanostructured according to embodiments herein the absorbance of light increases significantly and the reflectance also decreases significantly so that the metal layer 105 will appear dark. According to embodiments of the invention the nanostructured surface 102 is configured primarily to increase absorbance in the visible spectral range, i.e. in the spectral range from 300-700 nm.

Generally, the nanostructured product 100 may be a film, a foil, a part of an end-product or an end-product. Specific examples of a nanostructured product 100 comprise interior parts for cars, toys, household appliances, etc. For example, a surface of an interior part for cars may be provided with structurally coloured decorations, and a toy may be provided with a decoration by forming a nanostructured surface 102 in surface of the toy.

The substrate may be a polymer, a glass material, an oxide layer (e.g. anodized alumina) or other dielectric material that could be nanostructured. Any metal or other electrically conducting material which can be nanostructured may also be used as the substrate—but in this case the metal layer 105 on the nanostructured electrically conducting surface is not required. Accordingly, the entire product 100 may be made from the same substrate material where only a thin metal layer 105 is provided and possibly a transparent protective layer. Thus, it may be possible to decorate a product 100 with graphics or text by use of structural colours without a need to print a decoration on the object using pigmented paint. The substrate 101 may be opaque, transparent or semi-transparent.

The product 100 may be formed by moulding, e.g. injection moulding, by use of a mould, wherein a surface of the mould is provided with a nanostructured surface, so that the moulding creates the nanostructured surface 102 of the plastic object. Alternatively, the product 100 may be formed by hot embossing where an embossing tool is provided with a nanostructured surface so that the embossing creates the nanostructured surface 102 of the plastic object. The process for manufacturing the product 100 further comprises covering the nanostructured surface of the plastic object with a metal layer so that the metal layer at least partially covers the nanostructured surface and at least partially conforms to the nanostructured surface so that the metal layer generates broad band absorption of light in a visible spectral range.

The mould or embossing tool may be made using electroplating to make a metal mould from a silicon master or other master. Typically nickel or an alloy hereof is used in the electroplating process to apply a metal layer (e.g. 200 micrometre thick) on the nanostructured silicon master so that a metal layer with a negative pattern of the positive pattern on the silicon master is formed. In an embodiment the master is anodized aluminium where the oxide layer contains the nanostructures 103, or contains black silicon or nano-grass structures.

The process of covering the nanostructured surface of the plastic object with a metal layer may be performed using physical vapour deposition (PVD), e.g. electron beam PVD wherein an electron beam is used to evaporate the metal from solid/liquid phase to gas phase. The gas condenses as a thin film on the nanostructured surface and forms the metal surface 105. Alternatively, the process of covering the nanostructured surface of the plastic object with a metal layer may be performed using sputtering, which may be particularly useful in industrial processes.

In case the substrate 101 is a metal or other electrically conducting material the nanostructured surface 102 is provided in the substrate but without an additional metal layer 105. For example the product 100 may be a metal foil wherein the nanostructured surface 102 is provided, e.g. embossed directly into the metal foil. The metal substrate may be provided with a layer of dielectric material, e.g. a polymer, a glass material or an oxide layer. Accordingly, the nanostructured product 100 may be configured so that it comprises a metal substrate comprising a nanostructured surface, comprising raised or depressed nanostructures, and a layer of dielectric material at least partially covering the nanostructured surface and at least partially conforming to the nanostructured surface so that the nanostructured surface generates broad band absorbance of light in a visible spectral range.

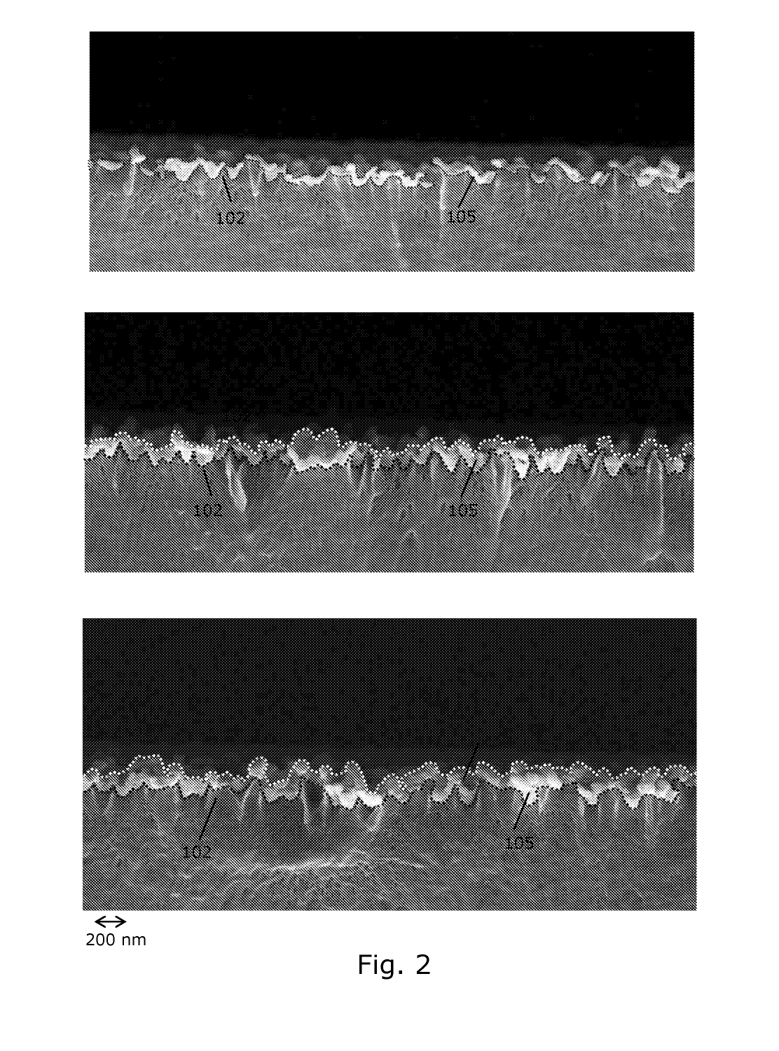

FIG. 2 shows examples of nanostructured surfaces 102 with protruding elongate structures covered with a metal layer 105. The cross sectional views in FIG. 2 are obtained by scanning electron microscopy. The thicknesses of the metal layers 105 in the upper, middle and bottom figures are 40, 60 and 100 nanometre, respectively. A 200 nm scale is shown.

FIG. 2 shows that that the metal layer may not fully conform to the nanostructured surface since the metal may have difficulties in covering narrow valley structures of the nanostructured surface 102 and since metal may have difficulties in covering narrow peak structures of the nanostructured surface 102. Similarly, there may be holes in the metal layer 105 so that some parts of the nanostructured surface 102 is not fully covered with the metal layer. Despite of these issues, it is true that the metal layer at least partially covers the nanostructured and conforms to the nanostructured surface so that the metal layer comprises a nanostructured surface comprising raised or depressed structures corresponding to the raised or depressed structures of the substrate 101, and so that the conforming nanostructured layer exhibits increased absorbance and decrease reflectance relative to metal surfaces that are not nanostructured.

FIG. 2 shows an embodiment of the invention wherein the nanostructures 103 are arranged in a random or at least non-periodic pattern. For example, the randomly arranged nanostructures 103 may be fabricated using methods corresponding to know methods for manufacturing black silicon, also known as nano-grass. Other suitable methods includes KOH (potassium hydroxide) wet etching and plasma etching of polymer.

In an embodiment the randomly arranged nanostructures 103 are present in an oxide layer. The oxide layer is present on a metal such as aluminium, titanium, zinc, magnesium or other metal and the oxide layer is obtained by anodizing the metal. The dielectric oxide layer obtained by anodizing has a porous nanostructured surface 102. The metal layer 105 can be a provided on the oxide layer to create e.g. dark or black structures on the oxide layer.

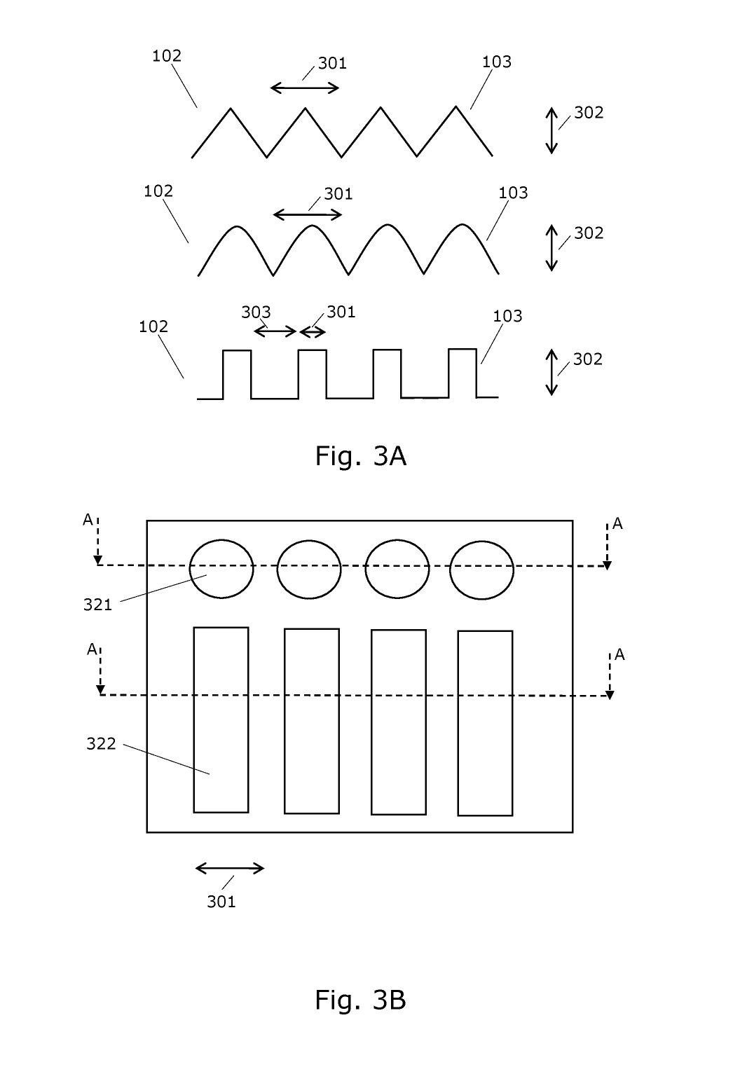

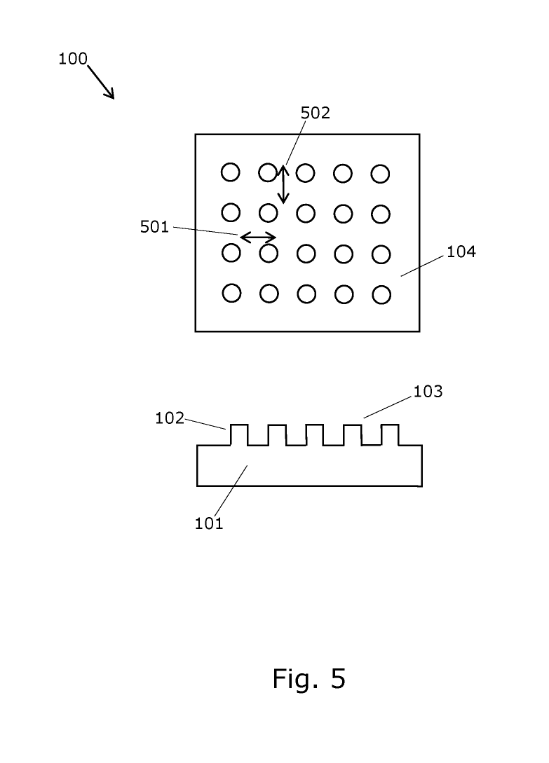

In order to achieve a low reflectance the raised or depressed structures 103 should be packed as densely as possible so that the area of a generally flat surface of the base plane 104 is as small as possible. That is, a generally flat surface will have a relatively high reflectance which may be undesired. In an embodiment the coverage of the raised or depressed structures 103 of the metal layer 105 relative to the base plane of the metal layer is greater than at least 30 percent, but preferably greater than 90 percent. A high coverage, e.g. above 90 percent, is possible when the nanostructures have a tapered shape such as the triangular shaped structures shown in FIG. 3A. A lower coverage of about 50 percent may be feasible when the nanostructures have pillar-like shapes. In general the high coverage of at least about 90 percent applies for tapered periodically or non-periodically nanostructures, whereas a lower coverage less than about 60 percent applies for periodically or non-periodically nanostructures having steep edges like pillar-shaped structures. See FIG. 5 for an embodiment with periodically located nanostructures 103.

FIG. 3A illustrates cross-sectional views of different principal shapes of raised nanostructures 103. Similar depressed nanostructures can be made by forming structures into a substrate 101. The triangular-shaped cross-sectional views in the upper drawing may be obtained by e.g. pyramid-shaped protruding features, the sinusoidal-shaped cross-sectional views in the middle drawing may be obtained by e.g. 3D-parabolic-shaped protruding features, and the rectangular-shaped cross-sectional views in the bottom drawing may be obtained by e.g. protruding cylinders or other pillar-shaped structures. The nanostructures 103 are formed on a plane or curved surface of a substrate 101.

FIG. 3A shows the width 301 and height 302 of the nanostructures and the spacing 303 between nanostructures. For nanostructures of the type shown in the upper and middle drawing the spacing 303 between nanostructures 103 is close to zero, at least at some locations of neighbour nanostructures and depending on the 3D-shape of the structures. For the nanostructures of the type shown in the upper and middle drawing the period of the nanostructures 103 is the same or substantially the same as the width 301, whereas, for the nanostructures with a spacing 303 between neighbour structures the period is the sum of the width 301 and the spacing 303.

The width 301 may be in the range from 10 to 2000 nm. The absorbance effect seems to be most efficient for widths 301 below 300 nm, although absorbance effects are also present above 300 nm and up to 1 micrometre. Above 1 micrometre the absorbance effect becomes smaller. Widths above e.g. 200 nm, e.g. in the range from 250-750 nm may be preferred due the higher mechanical robustness of compared to smaller widths. The width may be the diameter of a structure 103, a maximum, a minimum or an average width of a protruding or recessed structural feature 103

The period of the nanostructures may be in the range from 10 to 2000 nm. For periods above 150 nm diffraction effects start to take place for periodically arranged nanostructures. Since some diffraction may be acceptable periods above 150 nm may be acceptable for periodic structures. For non-periodic or random structure diffraction effects are minimal.

The heights 302 may be in the range from 50 to 5000 nm. Heights in the range from 100 to 300 nanometres may be preferred for optimum absorption.

FIG. 3B illustrates top views of the cross-sectional views from FIG. 3A. FIG. 3B also shows the location of line AA of the cross-sectional views in FIG. 3A.

FIG. 3B shows that the nanostructures 103 may be point-like structures 321 having substantially the same extension 301 in two orthogonal planar directions. Alternatively or additionally, the nanostructures 103 may be elongate 322 structures having an extension in one planar direction which is at least twice the width 301. The elongate planar extension may be straight or curved and the length of the planar extension may range from e.g. 100 nm to several micrometre or even several millimetre.

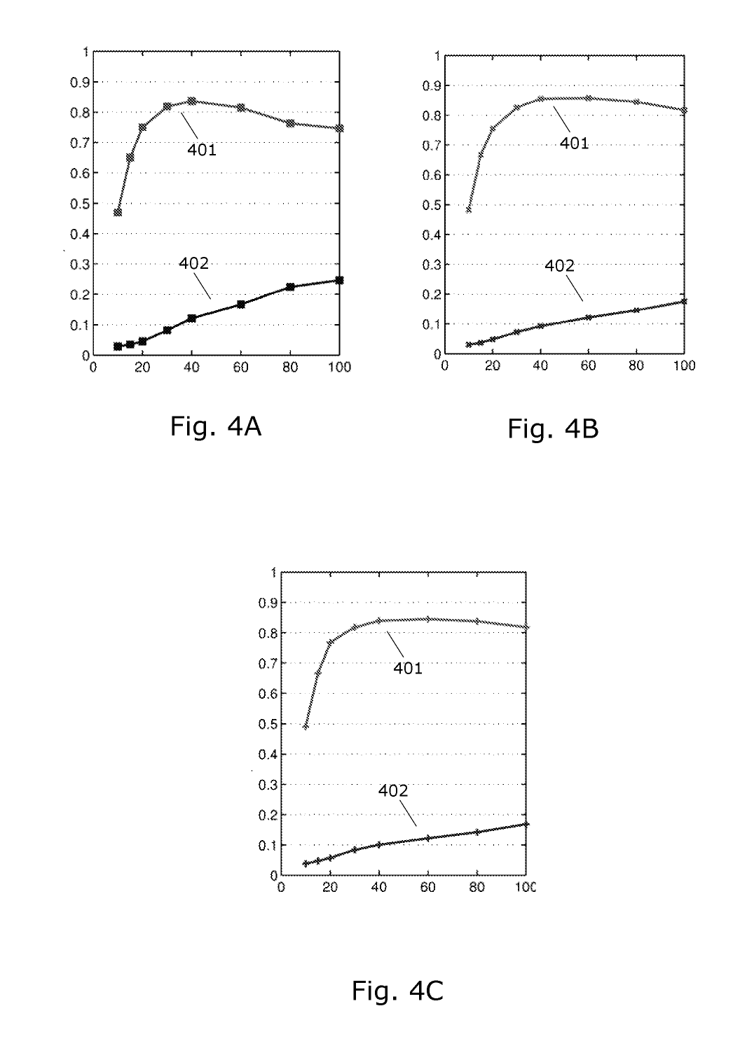

FIGS. 4A-C show experimentally obtained absorbance values 401 and reflectance values 402 (along the ordinate) for incident light at 500 nm as a function of the thickness of the metal layer (along the abscissa). The reflectance values 402 include both specular and scattered light from the surface of a metal layer 105. The data in FIGS. 4A-C where obtained from non-periodically arranged nanostructures 103 wherein nanostructures 103 have a width of 100 nanometre and a height of 200 nanometre in the results in FIG. 4A, a width of 150 nanometre and a height of 300 nanometre in the results in FIG. 4B, a width of 250 nanometre and a height of 500 nanometre in the results in FIG. 4C. Thus, although the absorbance and reflectance curves 401, 402 depend on the dimension of the nanostructures, the curves in FIGS. 4A-C show similar absorbance and reflectance curves from nanostructures with widths in the range 100-250 nanometre and heights in the range 200-500 nanometre. It is believed that similar or at least acceptable absorbance and reflectance values are obtainable from nanostructures with widths in the range 100-2500 nanometre and heights in the range 200-5000 nanometre. For the larger heights and widths, e.g. widths about 1000 nanometre, the ratio of heights and widths may be chosen so that scattering is minimised, e.g. by choosing heights that are approximately twice the widths.

In FIGS. 4A-C, the reflectance and absorbance values are obtained for incident light at 500 nm. However, since the reflectance, absorbance and transmittance values substantially do not depend on wavelength in the visible range (300-700 nm), the data in FIG. 4 are also applicable for other wavelengths in the visible range so that the reflectance and absorbance values in FIG. 4 are applicable as average percentages over the visible range.

The curves 401, 402 in FIG. 4 suggest that the thickness of the metal layer is in the range from 10-80 nm, e.g. in the range from 20-50 nm in order to obtain absorbance values above 65 percent and reflectance values below maximum 20 percent in average over the visible spectral range. Such absorbance values may be sufficient for obtaining a surface which appears dark. If the reflectance becomes greater than 30-40 percent the surface will appear reflective and have a mirror-like appearance.

In practice an average broad band absorption of light in a visible spectral range of at least 20 percent in average over the visible spectral range may be sufficient for achieving a dark surface. Particularly, for opaque substrates a relatively low absorbance of 20 percent and a corresponding relatively high transmittance of the metal layer 105 (but still a low reflection of max. 20 percent) may be sufficient for achieving a dark surface since light has to traverse the metal layer 105 twice (i.e. light which is not absorbed in the first traversal of the metal layer and which is reflected at the interface between the metal layer 105 and the nanostructured surface 102 will have to traverse the metal layer 105 a second time and, therefore, be expose to absorption a second time).

The absorbance and reflectance values in FIG. 4 have been obtained with an aluminium layer 105. According to an embodiment, aluminium is preferred for the metal layer 105. Other metals like gold or silver are also applicable, but may be less preferred due to the higher cost of these materials compared to aluminium, which may be important particularly for high volume production using e.g. injection moulding.

The reflectance, absorbance and transmittance values referred to herein are defined as the ratio of incident power of light and reflected, absorbed or transmitted power of light.

By applying a pattern provided with the nanostructured surface 103 and metal layer 105 over a surface of a substrate 101 the product 100 obtains a structurally coloured decoration, e.g. text or other graphics, i.e. a coloured decoration which has a substantially monochrome dark appearance. The dark appearance may be black or grey depending on the absorbance of the nanostructured metal layer 105.

The product 100 may further be configured so that the substrate 101 comprises a scattering surface. As illustrated in FIG. 1 the scattering surface 110 may be embodied as a rough surface with scattering structures 111 having dimensions which are large enough to scatter incoming light. Such scattering structures may have dimensions, i.e. dimensions in the plane of substrate and perpendicular to the substrate, where dimensions in the plane of the substrate (e.g. a diameter of a protruding structure) is in the range from 1 micrometre to 1 millimetre and where dimensions perpendicular to the substrate (e.g. a height of a protruding structure is in the range from 100 nanometre to 200 micrometre. The scattering surface 110 may or may not be covered with a metal layer 105. Particularly if the surface of the substrate has good reflection properties, e.g. if the surface has a light colour, a metal layer 105 may not be required. However, if optimum scattering properties are sought or if the substrate 101 is not suited for scattering, the scattering surface may be covered with the same metal layer 105 as the nanostructured surface 102.

The rough scattering surface of the substrate may be manufactured by sandblasting areas which should have a scattering effect.

The substrate 101 may exhibit good scattering features in itself in which case the surface need not be configured as a rough surface with scattering structures 111.

The scattering surface may be located adjacent to the nanostructured surface so that a high visual contrast is generated between the dark nanostructured surfaces 102 and the bright scattering surfaces.

In an embodiment the substrate 101 is configured with a plurality of scattering surfaces and a plurality of the nanostructured surfaces 102 arranged in a pattern with alternating scattering surfaces and nanostructured surfaces. The pattern of alternating dark and bright areas may be used for generating surfaces which appear brighter than the dark areas of the nanostructured surfaces 102 and darker than the bright areas of the scattering surfaces, i.e. for generating grey scale colours.

Alternatively or additionally, grey scale colours may be achieved by the geometry of the nanostructures, e.g. by forming nanostructures 103 having heights 302 or equivalent depths which are relatively low (e.g. compared to surrounding nanostructures 103 configured for generating darker surfaces) whereby the reflectance from such structures is increased so that the surface appears more grey.

Additionally or alternatively, the product 100 may further be configured with a specular reflective surface 120. The specular reflective surface may be embodied by the substrate 101 configured with a non-structured surface covered by the metal layer 105. Such non-structured surface covered by a metal layer will have a high reflectance and a mirror-like appearance. The specular reflective surface may be located adjacent to the nanostructured surface and/or the scattering surface so that a high visual contrast is generated between mirror-like surface and the dark nanostructured surfaces 102 and/or the bright scattering surfaces.

As shown in FIG. 1 the metal layer 105 covering the nanostructured surface 102 may be covered with a transparent protective layer 130. Additionally, other surfaces of the substrate 101 such as the specular reflective surface and/or the scattering surface may also be covered by a transparent protective layer 130. The transparent protective layer 130 may have a scattering effect, e.g. achieved by scattering structures such as scattering spheres/particles or irregularities included in the protective layer or on the surface of the protective layer. Alternatively or additionally, the scattering effect of the transparent protective layer 130 may be achieved using polymer materials which inherently have scattering properties.

The nanostructured product may be in the form of a film or foil configured to be connected to another object, e.g. via an adhesive layer. According to this example the film-substrate is embodied by the substrate 101. A metal layer 105 is provided on a front face of the film-substrate which is provided with the nanostructured surface 102. A back face of the film is configured, e.g. with an adhesive layer, for enabling connection to an object.

Alternatively the film product may be configured so that the metal layer is located on a back face of the foil, and so that the back face is configured to be connected to an object. According to this embodiment the film is transparent so that light is able to propagate through the film to the nanostructured metal surface 105. An adhesive layer may be provided on the back face and thereby on the nanostructured metal surface 105. Since the adhesive layer, which may be a glue or curable polymer, is soft the adhesive layer does not affect the structures of the nanostructured surface 102 significantly.

FIG. 5 illustrates (top view and side view) an embodiment of the nanostructured product 100 wherein the nanostructures 103 of the nanostructured surface 102 are arranged periodically with constant or substantially constant periods 501, 502 in two orthogonal planar directions.

The periodically arranged nanostructures 103 generally have a height in the range of 50-150 nanometre with a preferred height of 100 nanometre. The lateral size, e.g. diameter, of the periodically arranged nanostructures 103 is generally in the range of 10 to 350 nanometre, and the lateral spacing of the nanostructures 103, i.e. distance between neighbour nanostructures 103 along the directions of the periods 501, 502, is generally in the range from 20-400 nanometre. Ideally the period 501, 502 should be maximum 150 nanometre in order to avoid diffraction. However, since some diffraction may be allowed the period may also be greater than 150 nanometre.

The periodically arranged nanostructures 103 may be configured as raised or depressed nanostructures relative to the base plane 104 of the substrate 101. A metal layer 105 (implicitly indicated in FIG. 5) is applied to the nanostructured surface 102 so that the metal layer at least partially covers the nanostructured surface 102 and at least partially conforms to the nanostructured surface so that the metal layer generates broad band absorbance of light in a visible spectral range.

FIG. 5 shows that the nanostructures have a pillar-like shape with steep edges. For the periodically arranged nanostructures 103 having pillar-like shapes the filling factor, i.e. the coverage of the raised or depressed nanostructures of the conforming metal layer relative to the base plane 105 of the metal layer, is greater than 30 percent and preferably about 50 percent.

Instead of having pillar-like shapes, the periodically arranged nanostructures in FIG. 5 may have tapered shapes. In case the periodically arranged nanostructures have tapered shapes the filling factor may be greater than 90 percent.

Accordingly, the periodically arranged nanostructures may have any of the cross-sectional shapes of the non-periodically arranged nanostructures shown in FIG. 3A. Furthermore, the periodically arrange nanostructures may have point like shapes 321 or elongate shapes 322 as shown in FIG. 3B.

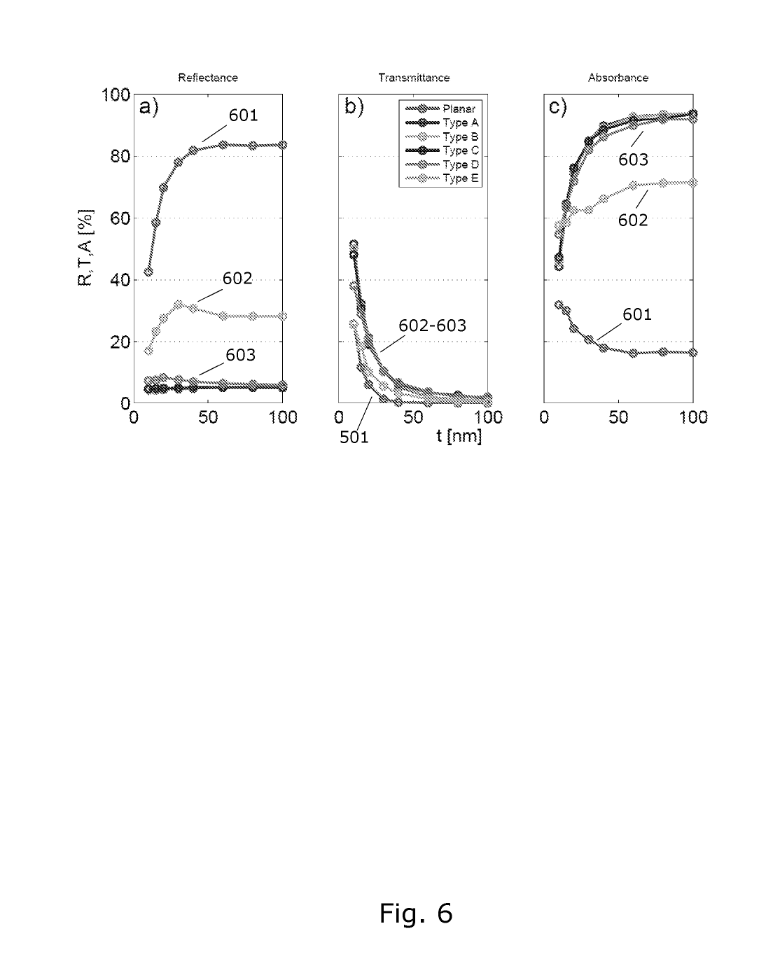

FIGS. 6A-C show measured reflectance (FIG. A), transmittance (FIG. B), and calculated absorbance (FIG. C) for different structures as a function of film thickness t, at 500 nm wavelength. Due to the relatively low dispersion, the optical properties at 500 nm wavelength sufficiently represents the optical properties within the visible spectrum. Absorbance A is calculated according to A=1-Reflectance-Transmittance.

The different structures, which are non-periodic, are characterised as types A-E:

Type A has heights 302=315±35 nm and an approximate width 301=150±10 nm. The approximate width corresponds to an approximate period of the non-periodic structures.

Type B has heights 302=450±50 nm and an approximate width 301=160±10 nm.

Type C has heights 302=615±80 nm and an approximate width 301=195±10 nm.

Type D has heights 302=815±120 nm and an approximate width 301=230±15 nm.

Type E has heights 302=880±140 nm and an approximate width 301=245±15 nm.

Curves 601 show results for a planar metal layer, i.e. a layer without a nanostructured surface. Curves 602 show results for structure E. Curves 603 show results for structures A-D.

The different structures A-E in FIGS. 6A-C are present in a nanostructured product configured so that the substrate is a front layer configured to receive incident light so that the metal layer is provided on the back surface of the substrate containing the nanostructured surface. The substrate may be transparent or translucent, i.e. the substrate may be configured to diffuse light, e.g. by including scattering particles in the substrate or provide the substrate with a scattering surface.

The nanostructured product where the substrate is a front layer may be in the form of a film product configured so that the metal layer is located on a back face of the foil, and so that the back face is configured to be connected to an object, e.g. by means of an adhesive or sticky layer applied to the back of the metal layer. According to this embodiment the film is transparent and possibly provided with scattering means (scattering particles or surface) so that light is able to propagate through the film to the nanostructured metal surface 105.

The reflectance of the nanostructured thin films 602-603 is changed dramatically, compared to the planar thin film 601. The reflectance of the planar film increases rapidly, while the nanostructured thin films of type A-D show only a slight increase in reflectance, to a maximum of 6% for a thickness of 100 nm. The transmittance decreases rapidly for both the planar and the structured films although the transmittance of the nanostructured films is significantly larger than the planar. The decay in transmittance is also slower for the nanostructured films, compared to the planar. The reduced reflectance of the nanostructured films result in a dramatic increase in the absorbance, which increases to 90% for the nanostructured films of type A-D.

FIGS. 6A-C suggests that for a nanostructured product, configured so that the substrate is a front layer configured to receive incident light, the thickness of the metal layer should be above 50 nm, preferably greater than 60 nm, and e.g. be in the range from 50 or 60 nm to 90 or 100 nm. Thick metal layers may be less preferred due to the increased manufacturing time and costs for thick metal layers. Accordingly since the absorbance curve flattens for thicknesses above 90 nm, a range from 50 or 60 nm to 80, 90 or possibly up 100 nm may be preferred.

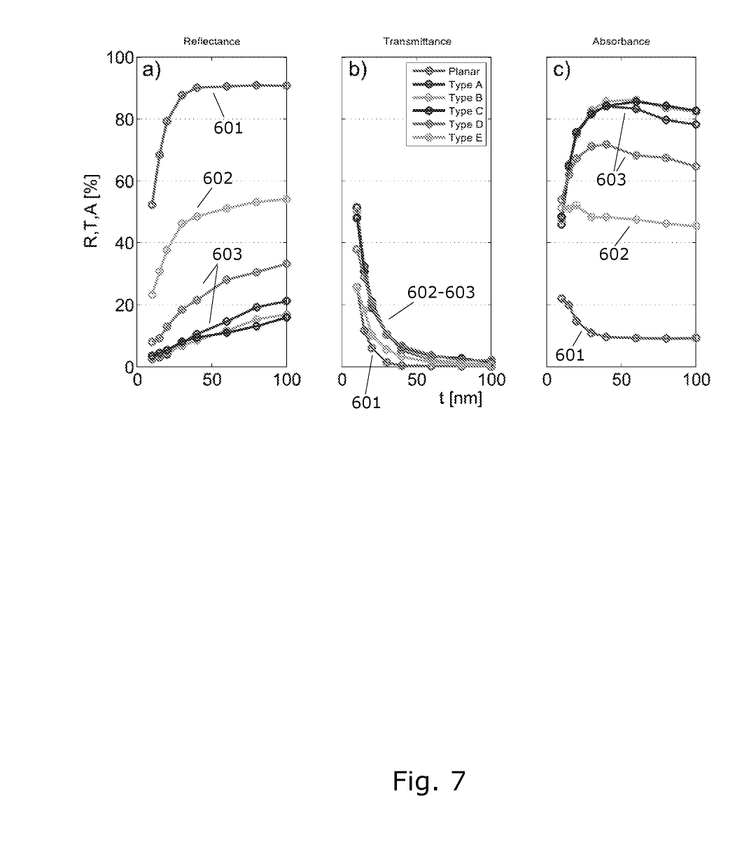

FIGS. 7A-C show measured reflectance (FIG. A), transmittance (FIG. B), and calculated absorbance (FIG. C) for different (non-period) nanostructures as a function of film thickness t, at 500 nm wavelength.

In FIGS. 7A-C, curves 601 show results for a planar metal layer, curves 602 for structure E and curves 603 for structures A-D as described in connection with FIGS. 6A-C.

The different structures A-E in FIGS. 7A-C are present in a nanostructured product configured so that so that the metal layer is a front layer configured to receive incident light. The substrate is provided on the back of the metal layer so that it receives light transmitted through the metal layer. The substrate may be transparent, translucent or opaque.

Advantageously, the substrate may be configured to scatter the light transmitted through the metal layer back to the metal layer, e.g. the substrate may be an opaque substrate. In this case, where the substrate is non-transparent and configured to scatter light back, light has to traverse the metal layer 105 twice since light which is not absorbed in the first traversal of the metal layer and which is scattered back by the substrate will have to traverse the metal layer 105 a second time and, therefore, be expose to absorption a second time.

FIG. 7B shows that the nanostructured metal surface is transparent up to a thickness of around 30 nm. The nanostructured metal layers still show very different behaviour than the planar metal films. However, the nanostructured metal layers (air-metal interfaces) show an increase in reflectance as function of metal thickness. This results in a trade-off between reflectance and transmittance, resulting in an optimum in absorbance for nanostructured metal layers having a thickness t in the range of 30-70 nm, such as in the range 40-60 nm. Depending on configurations of the nanostructured product useable absorbance may be achieved in a broader range from 10-80 nm, such as in the range from 20-70 nm, e.g. in the range from 20-50 nm.

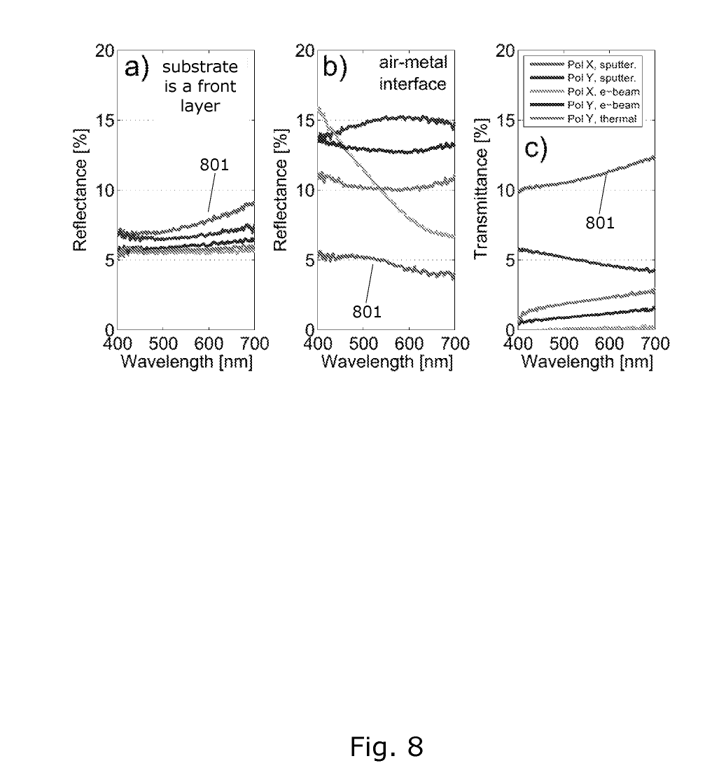

FIGS. 8A-B shows measured reflectance for different nanostructured products. The different nanostructured products are configured with different metal deposition methods including e-beam evaporation, thermal deposition and sputtering. Results from the product manufactured by sputtering as shown as curves 801.

In FIG. 8A the product is configured so that the substrate is a front layer configured to receive incident light. Here the results are very similar indicating that the manufacturing method is not critical.

In FIG. 8B the product is configured so that the metal layer is a front layer configured to receive incident light. Here the results are very different. The best results are obtained products manufactured using sputtering since the reflectance is about 5%, whereas other products show higher reflectance. FIG. 8C shows the transmittance corresponding to the results in FIG. 8B. Although the transmittance for products manufactured using sputtering is higher than transmittances for other products, this does not significantly reduce the absorption since the back scattered light from the substrate is transmitted a second time so that the effective transmission (forth and back) becomes approximately 1%.

FIGS. 8B-C suggests that metal layers formed by sputtering is preferred at least for products configured so that the metal layer is a front layer.

The advantageous results from sputtering manufacturing methods may be due to more smooth metal layers compared to the other methods. In the sputtering process the metal arrives at the nanostructured surface from different directions, whereas e-beam and thermal deposition produces highly directional depositions. The sputtering deposition may be achieved in a vacuum chamber wherein the metal source is irradiated by a plasma source which detaches metal from the source which attaches to the nanostructured surface.

The results in FIG. 8B-C apply to the results in FIG. 7A-C.

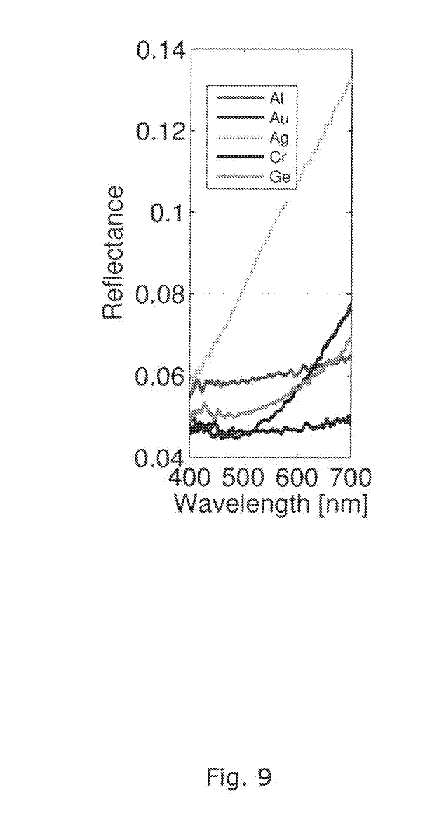

FIG. 9 shows measured reflectance for products wherein the substrate is a front layer wherein the metal layer is manufactured from Al, Au, Ag, Cr and Ge. The results shows that Al and Cr may be preferred metals. FIG. 9 also suggests that the metal layer in a product wherein the metal layer is the front layer is manufactured from Al or Cr. Accordingly, the measurements in FIG. 9 apply to products wherein the substrate or metal layer constitutes the front layer.

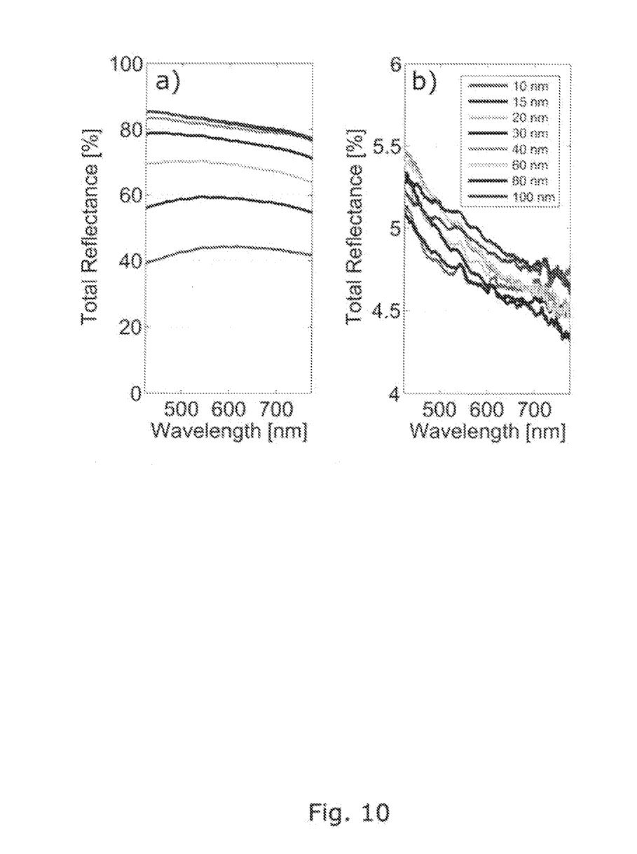

FIGS. 10A-B show the measured reflectance of planar and nanostructured thin metal films respectively. While the reflectance of a planar film increases dramatically with the film thickness, the nanostructured films show a remarkably low reflectance which virtually does not increase as function of metal film thickness. Furthermore, the dispersion in the reflectance is very small, amounting to below 1% (absolute percentage) within the visible spectrum. The measurements in FIG. 10B apply to products wherein the substrate or metal layer constitutes the front layer.

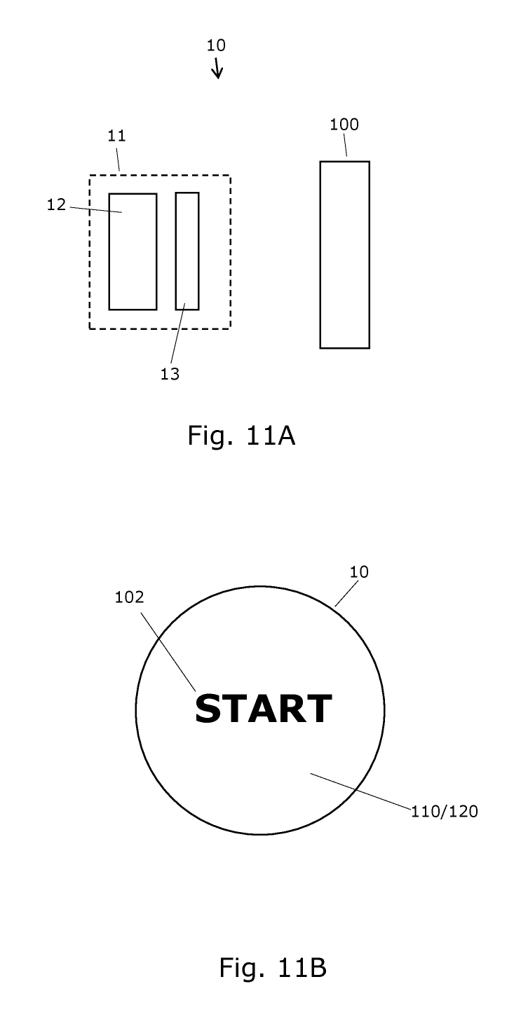

FIG. 11A illustrates an application of the nanostructured product 100 in a display 10. The display 10 comprises the nanostructured product 100 and a light source 11 arranged to emit light towards the nanostructured product.

The nanostructured product 100 may be arranged so that the metal layer 105 is a front layer configured to receive incident light from the surroundings and so that the substrate 101 faces the light source 11. Alternatively, the nanostructured product may be arranged so that the substrate 101 is a front layer configured to receive incident light from the surroundings and so that the metal layer 105 faces the light source. For reference, the face of the nanostructured product facing the surroundings is referred to as the front face, whereas the face of the nanostructured product facing the light source 11 is referred to as the back face.

Whether the metal layer 105 or the substrate 101 constitutes the front face, the nanostructured surface 102 may be configured according to any of the previously described embodiments. Specifically, the nanostructured surface 102 may comprise or be configured to create a pattern (i.e. a nanostructured pattern), e.g. in the form of a text, having a dark or black appearance due to the broad band absorption properties of the metal covered nanostructured surface 102 which constitutes the pattern.

The light source 11 may be configured in various ways. The light source may be a single light emitting device, e.g. a LED, an array of LEDs or for example an OLED element. Due to the reflectance properties of the nanostructured pattern the pattern of the front face will appear dark (where the pattern is configured to generate broad band absorbance) and the light source 11 will not be visible when the light source is off (not emitting light). When the light source in on, light from light source will be transmitted through the nanostructured pattern.

In another embodiment the light source 11 is provided with an image element 13, e.g. an LCD screen or other transparent graphical element, which is illuminated (from the back) by a light source 12. When the light source in on, the image or graphics will be visible through the metal covered nanostructured surface 102, which in this case may not comprise a nanostructured pattern, but may be configured as a window over the light source 11 or image element.

In order to make the nanostructured product 100 transparent or translucent for light from the light source 11, the substrate 101 should preferably by transparent or translucent. For example, the substrate 101 may be provided with scattering particles, in a volume or on a surface of the substrate 101, in or to make the brightness of transmitted light from the light source 11 uniform over the nanostructured pattern.

In an embodiment, the nanostructured product is configured so that the nanostructured pattern or the nanostructured window is located adjacent to a scattering surface, embodied by scattering structures in the substrate 101. Alternatively or additionally, the nanostructured product is configured so that the nanostructured pattern or the nanostructured window is located adjacent to a reflective surface, embodied by a metal covered non-structured surface in the substrate 101.

Advantageously, the nanostructured product 100 for use in a display 10 may be in the form of a film or foil configured to be connected to another object, e.g. a transparent or translucent support material configured to receive light from the light source 11. As described previously, the metal layer 105 may be provided on a front face or back face of a substrate 101 configured as a film.

The thickness of the metal layer 105 may be chosen according to a desired transmittance of the metal layer, i.e. the transmittance required for enabling sufficient transmittance of light from the light source 11. For example, according to FIG. 6, a metal thickness between 50 and 100 nm may be suitable in order to obtain a sufficiently high absorbance and sufficiently high transmittance.

In general the nanostructured product 100 for use in a display 10 may constitute a decorative or informative element in a display 10. For example, the nanostructured product 100 may be used to cover a backlit display in dashboard in a car. As another example, the nanostructured product 100 may be used in a warning light or in a button that lights up when it is pressed by a finger touch. For example, the display 10 may be configured as a hidden display which is only visible when it is turned on.

FIG. 11B shows an example of the display 10 configured as a button wherein the metal covered nanostructured surface 102 is arranged in a pattern to display “START” and wherein the substrate is configured to create a scattering surface 110 or a reflective surface as a background surface to the START-information. The START information will appear black when the light source 11 (located on a back side of the button) is off, and will appear with a colour of the light source when the light source is on.

While the invention has been illustrated and described in detail in the drawings and foregoing description, such illustration and description are to be considered illustrative or exemplary and not restrictive; the invention is not limited to the disclosed embodiments. Other variations to the disclosed embodiments can be understood and effected by those skilled in the art in practicing the claimed invention, from a study of the drawings, the disclosure, and the appended claims. In the claims, the word “comprising” does not exclude other elements or steps, and the indefinite article “a” or “an” does not exclude a plurality. The mere fact that certain measures are recited in mutually different dependent claims does not indicate that a combination of these measures cannot be used to advantage. Any reference signs in the claims should not be construed as limiting the scope.

1. A nanostructured product with a structurally coloured surface, comprising:
a substrate comprising a nanostructured surface, comprising raised or depressed nanostructures,
a metal layer at least partially covering the nanostructured surface and at least partially conforming to the nanostructured surface so that the metal layer generates broad band absorbance of light in a visible spectral range, wherein the thickness of the metal layer is in the range from 10-80 nm.

2-18. (canceled)

19. The nanostructured product according to claim 1, wherein the product is configured so that the metal layer is a front layer configured to receive incident light.

20. The nanostructured product according to claim 1, wherein the product is configured so that the substrate is a front layer configured to receive incident light.

21. The nanostructured product according to claim 1, wherein the substrate is opaque to visible light.

22. The nanostructured product according to claim 1, wherein the substrate is an oxide layer on a metal.

23. The nanostructured product according to claim 1, wherein the average broad band absorption of light in a visible spectral range is greater than 20 percent in average over the visible spectral range.

24. A nanostructured product according to claim 1, wherein the metal layer on the nanostructured surface has a reflectance of light in a visible spectral range which is less than percent in average over the visible spectral range.

25. The nanostructured product according to claim 1, where the metal layer conforms to the nanostructured surface so that the metal layer comprises a nanostructured surface comprising raised or depressed structures.

26. The nanostructured product according to claim 25, wherein the raised or depressed nanostructures of the substrate projects from a base plane, so that the raised or depressed nanostructures of the conforming metal layer also projects from a base plane of the metal layer, and wherein the coverage of the raised or depressed structures of the metal layer relative to the base plane of the metal layer is greater than 30 percent.

27. The nanostructured product according to claim 1, wherein the substrate further comprises a scattering surface.

28. The nanostructured product according to claim 27, wherein the scattering surface comprises structures having dimensions which are large enough to scatter incoming visible light.

29. The nanostructured product according to claim 27, wherein the scattering surface is located adjacent to nanostructured surface.

30. The nanostructured product according to claim 27, wherein the substrate comprises a plurality of the scattering surfaces and a plurality the nanostructured surfaces arranged in a pattern with alternating scattering surfaces and nanostructured surfaces.

31. The nanostructured product according to claim 27, wherein the substrate further comprises a non-structured surface covered by the metal layer.

32. The nanostructured product according to claim 27, wherein the substrate is a foil, wherein the metal layer is located on a back face of the foil, and wherein the back face is configured to be connected to an object.

33. The nanostructured product according to claim 1, wherein the metal layer is covered with a protective transparent layer.

34. A display comprising:
the nanostructured product according to claim 1, and
a light source arranged to emit light towards the nanostructured product.

35. A process for manufacturing the nanostructured product according to claim 1, comprising:
forming a plastic object by moulding or embossing by use of a mould or embossing tool, wherein a surface of the mould or embossing tool is provided with a nanostructured surface, so that the forming creates a nanostructured surface of the plastic object, and
covering the nanostructured surface of the plastic object with a metal layer so that the metal layer at least partially covers the nanostructured surface and at least partially conforms to the nanostructured surface so that the metal layer generates broad band absorption of light in a visible spectral range, where the thickness of the metal layer is in the range from 10-80 nm.
